(19) United States
(12) Patent Application Publication
(10) Pub. No.: US 2026/0120931 A1
(43) Pub. Date: Apr. 30, 2026

(54) INDUCTOR DEGRADATION REDUCTION IN 3D STACKED INTEGRATION WITH HYBRID BOND

(71) Applicant: XILINX, INC., San Jose, CA (US)

(72) Inventors: Jing JING, San Jose, CA (US); Shuxian WU, San Jose, CA (US)

(21) Appl. No.: 18/933,985

(22) Filed: Oct. 31, 2024

(51) Int. Cl. H01L 23/00; H01F 17/00; H01L 23/48; H01L 23/522; H01L 23/552; H01L 23/58; H01L 25/16

(52) U.S. Cl. CPC H01F 17/0006; H10D 1/20; H10W 20/20; H10W 20/497; H10W 42/00; H10W 42/20; H01F 2017/0073; H10W 80/312; H10W 80/327; H10W 90/00; H10W 90/798

(57) ABSTRACT

Embodiments herein describe an integrated circuit (IC) including an integrated circuit including a first die and a second die including an inductor and disposed over the first die, where the second die is electrically coupled to the first die via hybrid bonds (HBs). The IC may include a metal layer disposed under a portion of the inductor. The IC may further include a shielding layer disposed within the first die. The IC may also include first metal strips disposed adjacent a head section of the inductor and second metal strips disposed over a leg section of the inductor. The inductor may include a head section constructed as a dual loop and a leg section constructed as a pair of legs, where the inductor is enclosed within isolation walls.

### TECHNICAL FIELD

Examples of the present disclosure generally relate to circuits, and, in particular, to reducing inductor degradation in three-dimensional (3D) stacked integration with a hybrid bond (HB).

### BACKGROUND

The advancement of semiconductor technologies has driven the need for greater integration density, higher performance, and reduced power consumption in electronic systems. Traditional two-dimensional (2D) integrated circuits (ICs), while effective, face limitations in scaling due to physical constraints in planar die size and interconnect lengths, leading to increased signal delay and power dissipation. To address these challenges, 3D integrated stacking has emerged as a solution. This approach involves stacking multiple semiconductor dies vertically, enabling shorter interconnects between dies and more efficient use of space, thereby enhancing performance and energy efficiency.

An enabler of this technology is the hybrid bonding process, which allows for die-to-die interconnects with very fine pitch and high-density metal routing, eliminating the need for large bumps or traditional bonding methods. Hybrid bonding directly bonds the surface layers of dies, aligning metal interconnects and creating seamless electrical pathways between layers. Hybrid bonding improves signal integrity, reduces parasitic capacitance and resistance, and allows for the integration of heterogeneous components such as logic, memory, and analog devices in a compact 3D structure.

### SUMMARY

One embodiment described herein is an integrated circuit including a first die, a second die including an inductor and disposed over the first die, where the second die is electrically coupled to the first die via hybrid bonds (HBs), and a metal layer disposed under a portion of the inductor.

One embodiment described herein is an integrated circuit including a first die, a second die including an inductor and disposed over the first die, where the second die is electrically coupled to the first die via hybrid bonds (HBs), and a shielding layer disposed within the first die.

One embodiment described herein is an integrated circuit including a first die, a second die including an inductor and disposed over the first die, wherein the second die is electrically coupled to the first die via hybrid bonds (HBs), first metal strips disposed adjacent a head section of the inductor, and second metal strips disposed over a leg section of the inductor.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a cross-sectional view of a three-dimensional (3D) stacking integrated circuit (IC) using a hybrid bond (HB), according to an example.

FIG. 2 illustrates an inductor including a built-in isolation wall, according to an example.

FIG. 3 illustrates an interposer material or layer inserted underneath a head section of the inductor to minimize impact to inductor performance, according to an example.

FIG. 4 illustrates a shielding pattern or layer built within the lower interposer metal strips to suppress substrate noise, according to an example.

FIG. 5 illustrates metal routing to establish efficient power/ground connection without compromising inductor performance, according to an example.

FIG. 6 illustrates a method for constructing a 3D stacking IC to maintain high inductor performance, according to an example.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the embodiments herein or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

A serializer/deserializer (SerDes) includes a serializer to convert parallel data into a high-speed serial data stream and a deserializer to convert the high-speed serial data stream back into parallel data. SerDes is beneficial in high-speed data communication, enabling efficient transmission of large volumes of data over fewer physical connections. A chiplet is a small, functional block of an integrated circuit (IC) that can be independently designed, fabricated, and then integrated with other chiplets to form a complete system-on-chip (SoC). This modular approach allows for greater flexibility, improved yield, reduced development costs, and enhanced scalability in semiconductor design. A SerDes chiplet is a modular component within a chiplet-based architecture that implements SerDes functionality. A SerDes chiplet integrates the SerDes functionality into a distinct, reusable module that can be incorporated into larger chiplet-based systems. A SerDes chiplet provides for high-speed data transmission, modularity, scalability, and standardization.

The three-dimensional (3D) integrated stacking process refers to an advanced semiconductor fabrication technology where multiple layers of electronic circuits or chips or chiplets or SerDes chiplets are vertically stacked and interconnected to form a 3D structure. This technique enhances performance, power efficiency, and integration density in microelectronics compared to traditional two-dimensional (2D) planar chip designs. The 3D stacking process allows for tighter integration of different functional blocks, such as processors, memory, and other components, resulting in shorter communication distances and faster data exchange. As such, the 3D stacking process enables the integration of multiple chiplets, e.g., SerDes chiplets, into a compact form factor. By stacking the chiplets vertically, data communication paths can be shortened, leading to lower latency and higher bandwidth.

A chiplet can include one or more inductors. For example, an active chiplet can include one or more inductors. An active chiplet performs specific tasks, such as signal processing or data conversion. In a SerDes architecture, the active chiplet may be responsible for serializing and deserializing data, enabling efficient communication between different parts of a system or across interconnected systems. The inductor is a passive component integral to the SerDes chiplet's functionality. The inductor plays a role in filtering and impedance matching, which are beneficial for maintaining signal integrity during high-speed operations. Inductors help to stabilize the power supply to the active chiplet, reducing voltage fluctuations and noise that could degrade performance. The inductor may be positioned over the interposer die, within the active chiplet, to enhance performance and reduce parasitic effects. However, a distance between the inductor (within the active die) and the interposer die can have an impact on the inductor performance. Stacked dies or chiplets in 3D ICs can be connected by, e.g., a hybrid bond technique or a uBump technique. uBumps are small solder bumps that provide electrical and mechanical connections between dies or chiplets in a 3D IC stack. uBumps, however, may include limitations such as limited interconnect density due to the larger bump size and pitch, higher power consumption and resistance, and may face reliability challenges, particularly with thermal cycling. As such, when using certain SerDes chiplets, it may be preferable to use hybrid bonding.

Hybrid bonding is a more advanced interconnect technique, providing much finer interconnect pitches, improved electrical performance, and better scalability than uBump technology. Hybrid bonding combines direct metal-to-metal bonding and oxide bonding at the atomic level to create strong, reliable connections between stacked dies without using solder bumps. Hybrid bonding also allows closer placement of the inductor (within the active die) to the interposer die. However, reducing the distance between the inductor (within the active die) and the interposer die by using hybrid bonding may result in degraded performance of the inductor. Also, additional noise from the interposer and the through-silicon vias (TSVs) of the interposer used for vertical electrical connections may also negatively impact circuit performance.

In view of such challenges, the example embodiments present a method and system for achieving better inductor performance and low substrate noise in 3D integrated stacked ICs that use hybrid bonding. The main goal is to minimize the impact of the hybrid bonding on the inductor in the active die. The example embodiments significantly reduce inductor degradation in the integrated 3D stacked process using a hybrid bond (HB) with the interposer, which is beneficial for at least phased locked loop (PLL), voltage controlled oscillator (VC), and digitally controlled oscillator (DCO) circuit performance. The example embodiments effectively suppress noise from the interposer substrate and TSVs, which increases circuit performance and implement strategic power/ground routing and connections without compromising inductor performance.

The examples employ differentiated metal patterns in the head and leg sections or regions of the inductor to satisfy process requirements while maintaining high inductor performance. The differentiated metal patterns in the head and leg sections are made from interposer layers. The examples further implement strategic metal routing for a power/ground network by using metal strips outside an isolation wall of the inductor and prevent metal lines underneath the inductor head section, which greatly reduces the interposer impact to the inductor performance and by employing metal strips across an inductor leg section to facilitate efficient power/ground connection. The examples also provide a noise shielding layer within a lower interposer layer to suppress noise from the interposer substrate and TSVs without compromising inductor performance.

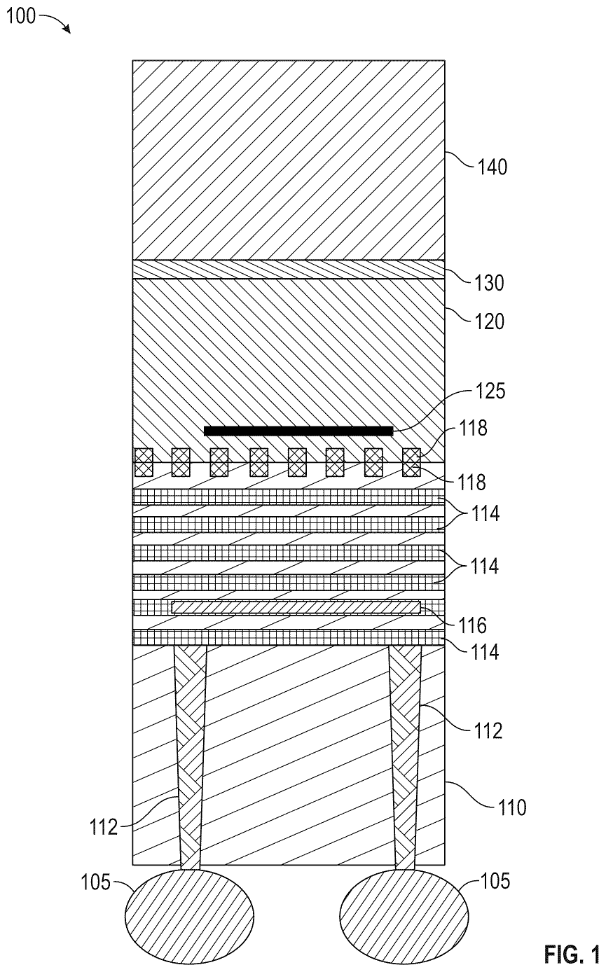

FIG. 1 illustrates a cross-sectional view of a three-dimensional (3D) stacking integrated circuit (IC) using a hybrid bond (HB), according to an example.

The IC 100 includes an active chiplet die 120 formed over and in direct contact with an interposer die 110. The interposer die 110 is coupled to bumps 105. The interposer die 110 includes through-silicon vias (TSVs) 112 and a plurality of metal layers 114. The interposer die 110 also includes a shield or shielding pattern or shielding layer 116. The active chiplet die 120 has an inductor 125. The active chiplet die 120 is coupled to the interposer die 110 via the HB 118. An oxide layer 130 may be formed over the active chiplet die 120. A silicon (Si) layer 140 may be formed over the oxide layer 130. The oxide layer 130 may have a thickness of about 1 um. The Si layer 140 serves as a mechanical support with no electrical connections. In one example, further dies, such as active dies, may be used on top of the active chiplet die 120 to form a module with additional active stacked dies.

The interposer die 110 is a passive interposer. The interposer die 110 serves as an intermediary layer that facilitates electrical connections between different semiconductor dies (chips) or between a die and external components, without incorporating any active electronic components of its own, thus referred to as a passive interposer. Passive interposers can be made from materials like silicon, glass, or organic substrates and have conductive pathways (such as copper traces) that route signals and power between the interconnected components. In the example, the interposer die 110 serves as a substrate that interconnects the active chiplet die 120 with other components, such as additional chiplets, memory, or power management units. The interposer die 110 facilitates the routing of signals and power between the stacked elements, allowing for efficient communication within the 3D architecture or IC 100.

The interposer die 110 includes the plurality of metal layers 114 to facilitate complex and efficient electrical routing between different components, such as chips or dies, without active elements such as transistors. The plurality of metal layers 114 allow for a higher density of connections by stacking traces vertically. With more metal layers, the interposer die 110 may have increased flexibility in, e.g., routing signals between components with different pin layouts. Each metal layer in the interposer die 110 serves to route signals, distribute power, or ground layers, and provides connections between the dies mounted on top of the interposer die 110 and the underlying packaging substrate (not shown). The example shows six metal layers or interposer metal layers. However, more or less metal layers may be used based on the application.

The interposer die 110 also includes the TSVs 112, which are vertical connections that pass through the interposer die 110, enabling high-density interconnects between the active chiplet die 120, the inductor 125, and any adjacent dies. The TSVs 112 help reduce the distance that signals travel, thereby lowering latency and improving overall performance. The use of the TSVs 112 also contributes to a compact design, allowing multiple chiplets to be integrated within a small footprint while maintaining high-performance characteristics. The TSVs 112 are beneficial for 3D integration because they provide a direct electrical path through the silicon, minimizing the distance and improving signal integrity compared to traditional wire bonding methods.

The bumps 105 may be, e.g., C4 bumps. C4 bumps are solder bumps used for connecting the bottom of the interposer die 110 to the substrate (or a printer circuit board (PCB) not shown). C4 bumps provide both electrical and mechanical connections between the interposer die 110 and underlying layers. The C4 bumps are placed on the bottom of the interposer die 110, and through the TSVs 112 and the plurality of metal layers 114. The bumps 105 provide connections to the active chiplet die 120 sitting on top of the interposer die 110. The bumps 105 collapse under heat, forming a strong bond between the interposer die 110 and a substrate (not shown) during assembly.

The functions of the interposer die 110 with the TSVs 112, the plurality of metal layers 114, and the bumps 105 include the interposer die 110 routing signals between the dies mounted on top through the multiple metal layers 114 and the TSVs 112, offering short, high-speed communication paths. The plurality of metal layers 114 also handle power delivery and ground connections to the dies, providing a stable electrical environment. By distributing power more efficiently and reducing signal bottlenecks, the interposer die 110 can help manage heat more effectively, especially in high-performance computing environments. The TSVs 112 and the plurality of metal layers 114 provide high-bandwidth, low-latency connections between dies, which is particularly beneficial in applications like high-performance computing (HPC), artificial intelligence (AI) accelerators, and graphics processing units (GPUs).

The active chiplet die 120 is a modular IC within a 3D integrated circuit (3D IC) that includes active components such as transistors, logic gates, or processing units. The active chiplet die 120 performs actual data processing, computing, or signal manipulation tasks, as opposed to passive chiplets, which serve primarily for interconnects or passive functions like routing or power distribution.

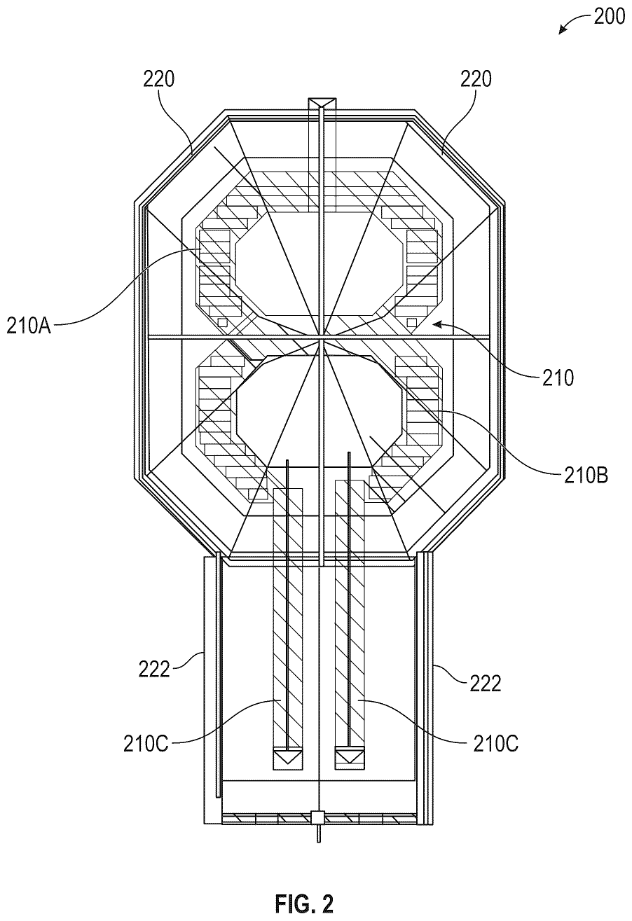

In the active chiplet die 120, the inductor 125 is often used in analog and mixed-signal circuits, particularly in power management, radiofrequency (RF), and clock generation applications. When the inductor 125 has a figure-eight design (FIGS. 2-5), such inductor usually serves specific purposes related to minimizing unwanted magnetic interference and enhancing performance. The inductor 125 can also be a transformer or different shaped inductor, depending on specific design specifications.

The inductor 125 in the active chiplet die 120 may provide for efficient power regulation, tuning and filtering of circuits, suppressing noise, and ensuring signal integrity. The inductor 125 may be used to improve the quality of signals being sent across the TSVs 112 in the interposer die 110. The inductor 125 can help filter noise signals, ensuring the interlayer communication remains robust even in high data rate systems.

The active chiplet die 120 is coupled or connected to the interposer die 110 via HB. HB is an advanced interconnect technique, providing much finer interconnect pitches, improved electrical performance, and better scalability than uBump technology. HB combines direct metal-to-metal bonding and oxide bonding at the atomic level to create strong, reliable connections between stacked dies without using solder bumps. HB allows for much smaller interconnects, with pitches in the range of 2-10 microns, which is significantly tighter than uBump, enabling much higher interconnect densities. In particular, using the hybrid bonding technology enables a distance between the inductor 125 and the HB 118 to be about 2 um (instead of 40 um using the uBump technology).

HB involves direct copper (Cu)-to-copper connections, which are achieved at room temperature or low-temperature processing. This metal bonding provides low-resistance, high-performance electrical connections without the need for solder. The absence of solder bumps reduces the interconnect resistance, leading to lower power consumption and higher signal integrity. HB is ideal for high-bandwidth, low-latency interconnections. The smaller interconnects in HB allow for better thermal management, as heat can flow more efficiently between the stacked layers, resulting in improved overall IC performance. The IC 100 can be used, e.g., in AI accelerators and GPUs.

Referring to the IC 100, the combination of the active chiplet die 120, the inductor 125, and the interposer die 110 with the TSVs 112 and the plurality of metal layers 114 creates a highly integrated solution that addresses challenges of modern data transmission. This architecture allows for improved signal integrity, enhanced performance, and reduced form factor. The close placement of the inductor 125 to the interposer die 110 (and the HB 118) helps minimize inductive and capacitive parasitics, ensuring clean and reliable signal transmission. The active chiplet die 120 can effectively handle high-speed data streams, benefiting from the low-latency connections provided by the interposer die 110. The 3D integration approach allows for a more compact design, which is beneficial in applications where space is limited, such as high-performance computing systems.

The design of a SerDes chiplet that incorporates the active chiplet die 120 with the inductor 125 over the interposer die 110 featuring the TSVs 112 provides highly integrated, compact solutions in semiconductor technology. This architecture not only enhances performance through reduced latency and improved signal integrity but also enables greater flexibility and scalability in modern electronic systems.

However, the proximity of the interposer die 110 (and the HB 118) to the inductor 125 to can affect the performance of the inductor 125 due to various electromagnetic, thermal, and material interference effects. As the distance between the interposer die 110 and the inductor 125 decreases (or the distance between the inductor 125 and the HB 118 decreases), several concerns may arise that can degrade the inductor's performance. For example, inductors operate based on electromagnetic fields, and the closer the interposer die 110, which has dense metal interconnects (the plurality of metal layers 114) is to the inductor 125, the greater the risk of electromagnetic interference (EMI). Also, when a time-varying magnetic field from the inductor 125 interacts with the conductive traces in the interposer die 110, eddy currents can be induced in the plurality of metal layers 114 of the interposer die 110. These eddy currents may create issues such as, e.g., power loss. Further, as the distance between the interposer die 110 and the inductor 125 decreases, parasitic capacitance between the inductor 125 and the interposer die's metal layers increases. This added parasitic capacitance can result in a shift in resonant frequency and degraded Q-factor.

To address inductor degradation from the proximity between the inductor 125 and the interposer die 110, FIGS. 2-5 below present several solutions.

FIG. 2 illustrates an inductor including a built-in isolation wall, according to an example.

In the configuration 200, the inductor 210 may be designed to have a figure-eight shape. The figure-eight inductor 210 offers advantages over a traditional spiral inductor. The figure-eight inductor 210 can reduce parasitic effects and improve performance, particularly in RF and high-speed applications. The figure-eight shape helps cancel out the magnetic fields produced by current loops in the two halves of the structure. This self-cancellation minimizes unwanted EMI and mutual inductance, especially when multiple inductors are present on the same die. By reducing the coupling between inductors or other signal paths, the figure-eight design enhances isolation, making the signal more immune to interference from nearby circuits.

Compared to traditional spiral inductors, figure-eight inductors can offer a more compact design with similar or improved inductance values, which is beneficial in dense chiplet layouts. The figure-eight shape optimizes the inductance while using less silicon area, which is useful for active chiplets where space is a premium. A limitation of spiral inductors is parasitic capacitance between adjacent turns, which can degrade performance at high frequencies. The figure-eight design mitigates this by reducing the overlap and interaction between loops.

The inductor 210 can include a head section and a leg section. The head section may include an upper head portion 210A and a lower head portion 210B. The leg section may include a pair of legs 210C. The pair of legs 210C may be coupled to the lower head portion 210B of the head section. The inductor 210 may be enclosed within isolation walls. The upper head portion 210A and the lower head portion 210B may be enclosed within isolation walls 220, which assume the shape of the figure-eight inductor. The pair of legs 210C may be enclosed within isolation walls 222, which define a more rectangular shape.

The isolation wall 220 is disposed around the upper head portion 210A and the lower head portion 210B of the figure-eight inductor 210. The isolation wall 220 physically isolates the figure-eight inductor 210 from external interference caused by other devices/components such as by mitigating coupling/interference from neighboring or adjacent channels. In an example, the isolation wall 220 is also configured to electrically isolate some portions of the inductor circuitry from the other devices/components. In one example, the isolation wall 220 prevents crosstalk between conductive portions of the inductor circuitry and conductive portions of the other devices/components and also mitigates parasitic capacitance between the conductive portions of the inductor circuitry and the conductive portions of the other devices/components.

The isolation wall 222 is disposed around the pair of legs 210C of the inductor 210. The isolation wall 222 physically isolates the pair of legs 210C of the figure-eight inductor 210 from external interference caused by other devices/components such as by mitigating coupling/interference from neighboring or adjacent channels. In an example, the isolation wall 222 is also configured to electrically isolate some portions of the inductor circuitry from the other devices/components.

As such, the entirety of the inductor 210, that is, the upper head portion 210A, the lower head portion 210B, and the pair of legs 210C are disposed or enclosed within the isolation wall 220 and the isolation wall 222. The isolation wall 220 and the isolation wall 222 collectively form a single, continuous wall.

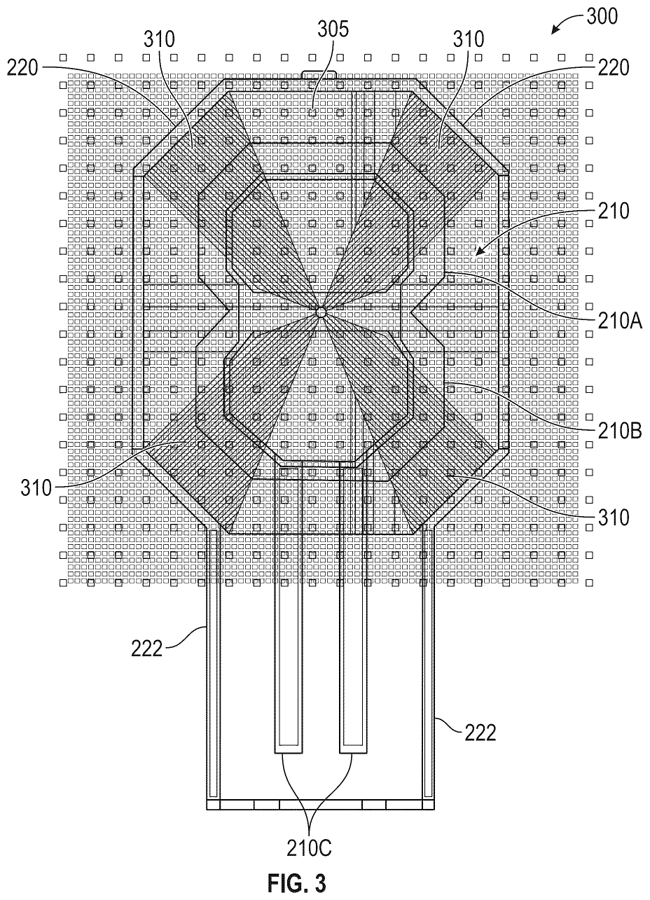

FIG. 3 illustrates an interposer material or layer inserted underneath a head section of the inductor to minimize impact to inductor performance, according to an example.

Two ground shielding layers are shown in the configuration 300, that is, a layer 305 and a layer 310. The layer 305 is constructed with the lowermost layer, e.g., the MO layer, which is part of the active chiplet die 120. The layer 310 is constructed with a lower interposer layer, e.g., the Mz layer. The layer 305 and the layer 310 are placed underneath the inductor head section. The layer 310 may be a metal layer. The layer 310 may provide for noise suppression under the inductor head section. The layer 310 may have a checkerboard pattern. Adding the layer 310 under the head section of the inductor 210 results in a similar inductance for high-frequency applications up to, e.g., 18 GHz. By adjusting the thickness and proximity of the layer 310 to the inductor 210, the inductance change be minimized and considered negligible. Adding the layer 310 under the head section of the inductor 210 results in a similar quality factor (Q) for high-frequency applications.

Moreover, the layer 310 may also be referred to as a differentiated interposer pattern. The term “differentiated” means that the pattern is customized or optimized to meet particular design requirements, i.e., to suppress noise. The differentiated interposer pattern further helps to meet density requirements and minimize impact to the performance of the inductor 210. The differentiated metal patterns in the head and leg sections are thus made from interposer layers.

One purpose of inserting the layer 310 under the head section of the inductor 210 is to suppress noise generated by the underlying layers of the IC 100, including active circuitry, interconnects, and other components. The layer 310 acts as a shield by reflecting or absorbing electromagnetic waves emitted by other active layers or components located below the head section of the inductor 210. This reduces electromagnetic coupling, preventing the inductor 210 from picking up unwanted signals or interference from these layers. In 3D ICs, noise from the interposer die 110, TSVs 112, or other elements beneath the active chiplet die 120 can couple into the inductor 125 through the substrate (not shown). The layer 310 serves as a barrier to block substrate noise, ensuring that the inductor's performance remains stable and free from interference. Components located beneath the inductor 210 may generate noise due to high current switching or signal transitions. The layer 310 helps contain these signals and prevents them from propagating upward, thereby maintaining signal integrity in the inductor and associated circuitry. Moreover, placing the layer 310 under the head section of the inductor 210 helps reduce parasitic capacitance and inductive coupling with other nearby elements, such as the TSVs 112, power traces, and active devices located on the lower layers of the IC 100.

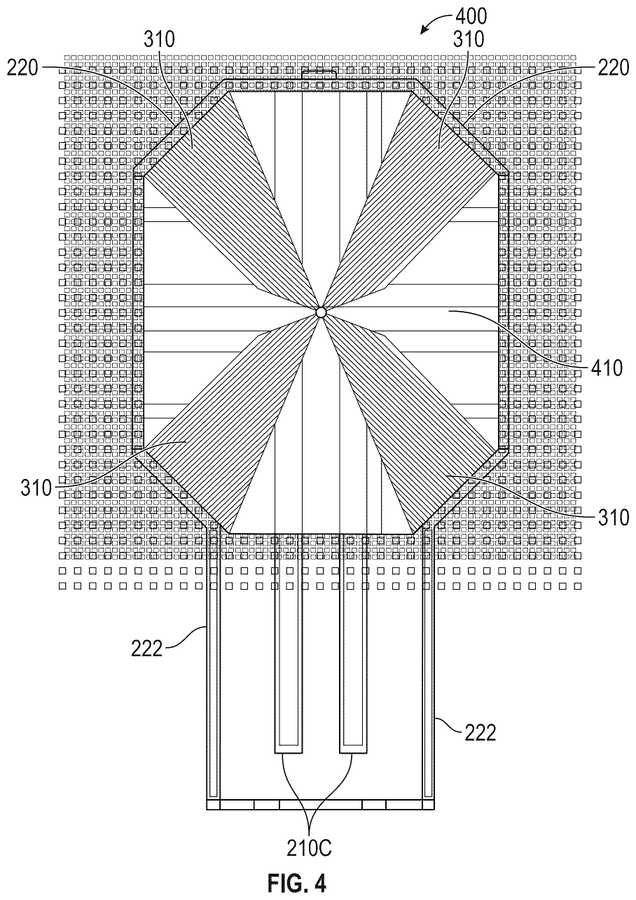

FIG. 4 illustrates a shielding pattern or layer built within the lower interposer metal strips to suppress substrate noise, according to an example.

The configuration 400 includes a shielding pattern or shielding layer 410 that extends adjacent the entire head section of the inductor 210. The shielding layer 410 may be the same as the shielding layer 116 in FIG. 1. The shielding layer 410 covers the entire head section of the inductor 210, and is electrically connected to ground. The shielding layer 410 is built into the interposer die 110 adjacent a top area of the TSVs 112. In one example, the shielding layer 410 may be strategically built into a lower Mz layer or metal layer of the interposer die 110. Positioning the shielding layer 410 in the interposer die 110 adjacent the top area of the TSVs 112 offers advantages in noise suppression, signal integrity, and thermal management. One benefit of placing the shielding layer 410 in the interposer die 110 adjacent the top area of the TSVs 112 is to block electromagnetic noise generated by the TSVs 112, signal routing and other components in the interposer die 110. The inductor 125 in the active chiplet die 120 is sensitive to EMI from neighboring components. If noise from the TSVs 112 and the circuitry or components in the interposer die 110 is not blocked, the noise can disrupt the inductance value, quality factor (Q), or overall signal integrity of the inductor 125. The shielding layer 410 effectively isolates the inductor 125.

The shielding layer 410 blocks or reduces EMI and coupling between the inductor 125 and other noisy elements, particularly the interposer die 110 formed underneath the active chiplet die 120. This ensures that the performance of the inductor 125 remains stable and unaffected by noise, especially in sensitive high-frequency applications. The shielding layer 410 is usually made from a conductive material like copper or a magnetic material like a ferrite or metal shield that can block both electric and magnetic fields. In some cases, a combination of materials can be used to optimize the shielding for specific frequencies.

As such, the interposer die 110 serves as an intermediate substrate, often used for signal routing, power distribution, or thermal management in advanced 3D IC designs. The interposer die 110 can generate noise due to the routing of high-speed signals or power lines. This noise can couple into the inductor 125 formed in the active chiplet die 120, affecting its behavior. The purpose of the shielding layer 410 is thus to block this noise from penetrating into the inductor 125, which is particularly sensitive to magnetic interference. By blocking unwanted noise, the inductor 125 can operate more efficiently, e.g., maintaining a higher Q.

The distance between the inductor 125 and the shielding layer 410 can be optimized to ensure that the shielding effectively isolates noise while not interfering with the inductor's own magnetic field. In the examples, the distance between the inductor 125 and the shielding layer 410 can be about 10 um to about 15 um.

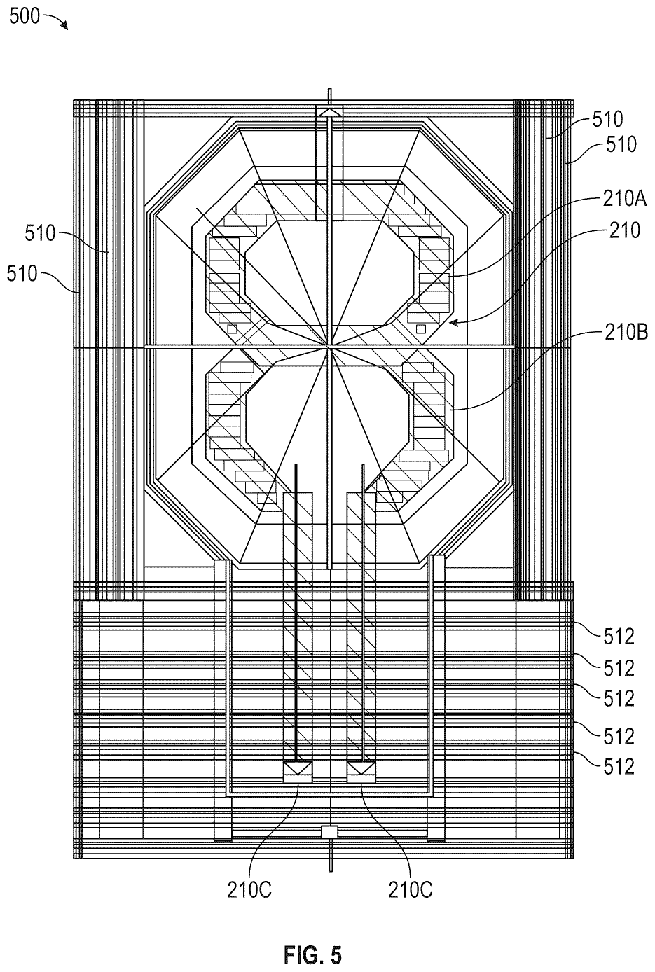

FIG. 5 illustrates metal routing to establish efficient power/ground connection without compromising inductor performance, according to an example.

In the configuration 500, metal strips are inserted adjacent the isolation walls 220 and over the isolation walls 222 enclosing the inductor 210. In one example, first metal strips 510 are placed adjacent the isolation walls 220 enclosing the head section of the inductor 210. The first metal strips 510 may be parallel to each other. The first metal strips 510 do not extend over the head section of the inductor 210. The first metal strips 510 only extend adjacent the head section of the inductor 210 outside the isolation walls 220 that enclose the head section of the inductor 210.

Placing the first metal strips 510 adjacent to the figure-eight inductor 210 for strategic metal routing of power and ground provides several benefits in terms of noise suppression, power integrity, and minimizing interference while ensuring minimal impact to the performance of the inductor 210. The figure-eight inductor 210 allows for natural noise cancellation due to its configuration, and the placement of the first metal strips 510 for power and ground routing can complement this design. The figure-eight inductor 210 has two loops oriented in opposite directions, resembling the number 8. This configuration provides certain benefits, such as magnetic field cancellation in areas where the fields from the two loops interact. Placing the first metal strips 510 adjacent to the figure-eight inductor 210 provides a strategic way to route power and ground signals while taking advantage of the spatial layout of the inductor 210. The goal is to ensure the first metal strips 510 do not interfere with the inductor's performance, particularly in terms of inductance, Q, and resonant frequency.

The first metal strips 510 for power and ground are placed adjacent to but not overlapping (or extending over) the active area of the inductor 210. Such placement avoids coupling between the inductor 210 and the first metal strips 510, which could alter the inductance or introduce losses. Placing the first metal strips 510 for power and ground adjacent to the inductor 210 ensures efficient use of die area without the need for additional space for routing further away from the inductor 210. This enables more compact designs without compromising on performance. The proximity of power and ground routing to the inductor 210 also helps reduce the length of signal paths, which can improve overall signal integrity and reduce parasitic effects. Further, power/ground routing close to the inductor 210 ensures that critical signals, such as supply voltages and ground, can be delivered with minimal inductance or resistance. This reduces issues like voltage drop or ground bounce, which can degrade the performance of nearby circuits.

In another example, second metal strips 512 are placed over the leg section of the inductor 210. The second metal strips 512 thus extend over the entire leg section of the inductor 210. The second metal strips 512 may be parallel to each other. The second metal strips 512 are perpendicular to the first metal strips 510.

Placing the second metal strips 512 over the leg section of the inductor 210 for strategic metal routing of power/ground is employed to ensure minimal impact on the inductor's performance, particularly in terms of its inductance and Q. The leg section of the inductor 210 refers to the straight segments below the looped portions. In this approach, the second metal strips 512 are placed above or over the leg sections, providing efficient routing of power and ground while minimizing interference with the inductor's magnetic field. The leg sections are more isolated from the core magnetic field as compared to the loops or turns (of the head section), making the leg sections better candidates for placing metal strips above them without heavily impacting the inductor's performance. As such, the second metal strips 512 for power and ground routing are strategically placed above the leg sections of the inductor 210, where the magnetic field strength is relatively weaker compared to the looped regions. The second metal strips 512 can carry power and ground signals across the die, providing low-resistance paths for stable power delivery to other parts of the circuit. The placement of second metal strips 512 over the leg sections accounts for the magnetic field distribution. The leg section generally has lower magnetic field intensity compared to the loops (or head section), so placing the second metal strips 512 over these sections minimizes electromagnetic interference with the inductor's core function.

The combination of the first metal strips 510 and the second metal strips 512 facilitate power/ground connections and have a minimal impact to the inductor performance. In examples, the impact may be considered negligible. The first metal strips 510 and the second metal strips 512 may be composed of, e.g., copper (Cu), aluminum (AI), tungsten (W), silver (Ag) or a combination thereof. The thickness of the first metal strips 510 and the second metal strips 512 may be between about 1 um to about 3 um for low-frequency applications. The thickness of the first metal strips 510 and the second metal strips 512 may be between about 0.5 um to about 2 um for high-frequency applications. In 3D IC packaging applications, the thickness of the first metal strips 510 and the second metal strips 512 may be between about 0.1 um to about 0.5 um, and can be referred to as ultra-thin metal layers. Adding the first metal strips 510 and the second metal strips 512 results in a similar inductance for high-frequency applications up to, e.g., 16 GHz. Adding the first metal strips 510 and the second metal strips 512 results in a similar quality factor (Q) for high-frequency applications up to, e.g., 20 GHz.

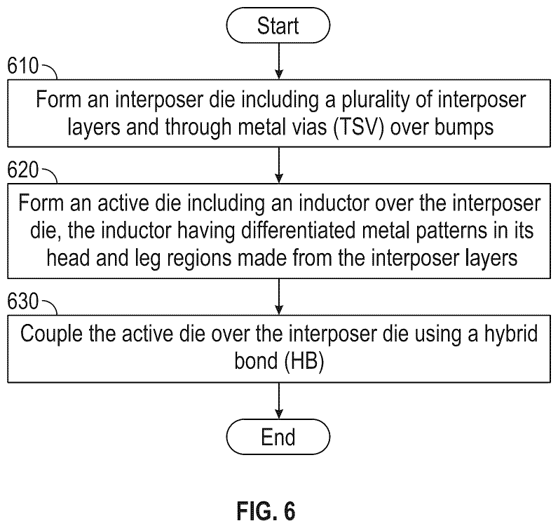

FIG. 6 illustrates a method for constructing a 3D stacking IC to maintain high inductor performance, according to an example.

At operation 610, an interposer die including a plurality of interposer layers and through metal vias (TSVs) is formed over bumps. The interposer die allows for signal routing between different dies or chips in a 3D IC package. The TSVs are vertical electrical connections that pass through a portion of the interposer die.

At operation 620, an active die including an inductor is formed over the interposer die, the inductor having differentiated metal patterns in its head and leg sections or regions. The differentiated metal patterns in the head and leg sections are made from interposer layers. The inductor may be designed to have a figure-eight shape. The inductor can include a head section and a leg section. The head section may include an upper head portion and a lower head portion. The leg section may include a pair of legs. The pair of legs may be coupled to the lower head portion of the head section. The inductor may be enclosed within isolation walls.

At operation 630, the active die is coupled to the interposer die using a HB. HB is an advanced interconnect technique, providing much finer interconnect pitches, improved electrical performance, and better scalability than uBump technology. HB allows for much smaller interconnects, with pitches in the range of 2-10 microns, which is significantly tighter than uBump, enabling much higher interconnect densities.

As such, many components of the interposer die 110 can generate noise. This noise can couple into sensitive analog components, such as the inductor 125 in the active chiplet die 120, leading to performance degradation. The various metals layers and metal strips described with reference to FIGS. 3-5 disposed adjacent to the head section of the inductor 125 can prevent noise from coupling into the inductor's magnetic field. In 3D ICs, cross-talk between nearby components may also be an issue. The various metals layers and metal strips described with reference to FIGS. 3-5 disposed adjacent to the head section of the inductor 125 can reduce the susceptibility of the inductor 125 to cross-talk.

In conclusion, the example embodiments present a method and system for achieving better inductor performance and low substrate noise in 3D integrated stacked ICs that use hybrid bonding. The main goal is to minimize the impact of the hybrid bonding on the inductor in the active die. The example embodiments, significantly reduce inductor degradation in the integrated 3D stacked process using a hybrid bond (HB) with the interposer. The example embodiments effectively suppress noise from the interposer substrate and TSVs, which increases circuit performance and implement strategic power/ground routing and connections without compromising inductor performance. The examples involve employing differentiated metal patterns in the head and leg sections or regions of the inductor to satisfy process requirements while maintaining high inductor performance. The differentiated metal patterns in the head and leg sections are made from interposer layers. The examples further implement strategic metal routing for a power/ground network by using metal strips outside an isolation wall of the inductor and prevent metal lines underneath the inductor head section, which greatly reduces the interposer impact to the inductor performance and by employing metal strips across an inductor leg section to facilitate efficient power/ground connection. The examples also provide a noise shielding pattern within a lower interposer layer to suppress noise from the interposer substrate and TSVs without compromising inductor performance.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. An integrated circuit comprising:
a first die;
a second die including an inductor and disposed over the first die, wherein the second die is electrically coupled to the first die via hybrid bonds (HBs); and
a metal layer disposed under a portion of the inductor.

2. The integrated circuit of claim 1, wherein the first die is an interposer die and the second die is an active die.

3. The integrated circuit of claim 1, wherein the first die includes a plurality of metal layers and through-silicon vias (TSVs) that provide electrical communication between the plurality of metals layers and bumps disposed under the first die.

4. The integrated circuit of claim 1, wherein the inductor has a figure eight shape.

5. The integrated circuit of claim 1, wherein the inductor has a head section constructed as a dual loop and a leg section constructed as a pair of legs.

6. The integrated circuit of claim 5, wherein the metal layer is disposed under the head section of the inductor.

7. The integrated circuit of claim 1, wherein the inductor is enclosed within isolation walls.

8. An integrated circuit comprising:
a first die;
a second die including an inductor and disposed over the first die, wherein the second die is electrically coupled to the first die via hybrid bonds (HBs); and
a shielding layer disposed within the first die.

9. The integrated circuit of claim 8, wherein the first die is an interposer die and the second die is an active die.

10. The integrated circuit of claim 8, wherein the first die includes a plurality of metal layers and through-silicon vias (TSVs) that provide electrical communication between the plurality of metals layers and bumps disposed under the first die.

11. The integrated circuit of claim 8, wherein the inductor has a figure eight shape.

12. The integrated circuit of claim 8, wherein the inductor has a head section constructed as a dual loop and a leg section constructed as a pair of legs.

13. The integrated circuit of claim 8, wherein the inductor is enclosed within isolation walls.

14. The integrated circuit of claim 8, wherein a distance between the inductor in the second die and the shielding layer in the first die is about 10 um to about 15 um.

15. An integrated circuit comprising:
a first die;
a second die including an inductor and disposed over the first die, wherein the second die is electrically coupled to the first die via hybrid bonds (HBs);
first metal strips disposed adjacent a head section of the inductor; and
second metal strips disposed over a leg section of the inductor.

16. The integrated circuit of claim 15, wherein the first die is an interposer die and the second die is an active die.

17. The integrated circuit of claim 15, wherein the head section of the inductor is constructed as a dual loop and the leg section of the inductor is constructed as a pair of legs.

18. The integrated circuit of claim 15, wherein the first metal strips are perpendicular to the second metal strips.

19. The integrated circuit of claim 15, wherein the second metal strips extend over the leg section of the inductor.

20. The integrated circuit of claim 15, wherein the first metal strips are disposed outside isolation walls enclosing the inductor.
